(19) United States
(12) Patent Application Publication
(10) Pub. No.: US 2025/0139315 A1
(43) Pub. Date: May 1, 2025

(54) TECHNIQUES FOR AUTOMATICALLY GENERATING BUILDING LAYOUT DESIGNS THAT REDUCE TRANSMISSION OF VIRUSES

(71) Applicant: AUTODESK, INC., San Francisco, CA (US)

(72) Inventors: Bokyung LEE, San Francisco, CA (US); Rhys GOLDSTEIN, Toronto (CA); Damon LAU, New York, CA (US); Michael LEE, Toronto (CA); Jeremy MOGK, San Francisco, CA (US); Jacobo Bibliowicz SCHUSTER, Toronto (CA); Alexander TESSIER, Toronto (CA)

(21) Appl. No.: 18/500,033

(22) Filed: Nov. 1, 2023

(51) Int. Cl. G06F 30/13; G06F 30/20

(52) U.S. Cl. CPC G06F 30/13; G06F 30/20

(57) ABSTRACT

In various embodiments, a building layout application generates building designs that reduce virus transmissions. The building layout application generates a first layout design set for a building based on a first design vector set and a baseline layout design. The building layout application executes, multiple times, a stochastic multi-agent virus simulator on a layout design included in the first layout design set and a simulation configuration to generate simulation results. The building layout application computes a risk score associated with both the layout design and a virus based on the simulation results. The building layout application executes evolutionary operations(s) on the first design vector set based on the risk score and at least one other risk score to generate a second design vector set. The building layout application generates a second layout design set for the building based on the second design vector set and the baseline layout design.

### BACKGROUND

### Field of the Various Embodiments

The various embodiments relate generally to computer science and computer-aided design software and, more specifically, to techniques for automatically generating building layout designs that reduce transmission of viruses.

### DESCRIPTION OF THE RELATED ART

The arrangement or “layout” of various spatial elements within a building can significantly impact the rate at which viruses are transmitted within the building. For example, both the air and surface transmission rates of coronavirus disease 2019 (COVID-19) typically vary based on the positions and orientations of desks, meeting rooms, restrooms, and other spatial elements within an office building. In an attempt to mitigate health risks associated with a target virus within a building, conventional computer-aided design (CAD) software can be used to specify the arrangement of flexible spatial elements within the building in order to reduce estimated air and/or surface transmission rates for the target virus.

During a typical layout process for a building design, a designer defines a building layout problem by using conventional CAD software to enter a baseline layout design representing fixed portions of the building and identify icons representing any number of flexible spatial elements to be placed within the building. The designer uses the conventional CAD software to position and orient the icons multiple times within the baseline layout design to generate a variety of different two-dimensional (2D) layout designs for the building. The designer then typically uses heuristic-based estimation software and/or simulation software to evaluate each layout design with respect to transmission of a given target virus. The designer discards sub-optimal layout designs and uses the conventional CAD software to modify any number of the remaining layout designs based on the virus evaluations. The designer continues to evaluate newly modified layout designs, discard sub-optimal layout designs, and iteratively modify the remaining layout designs until eventually selecting one or more layout designs for subsequent design activities.

One drawback of the above approach is that effectively exploring the design space associated with a typical building layout problem using conventional CAD software is difficult, if not impossible. In that regard, initially generating and subsequently modifying building layout designs via conventional CAD tools is normally very time-consuming. Accordingly, with the limited amount of time normally allocated for a layout process for a building design, usually only a handful of layout designs can be initially generated and relatively few modifications can be made to the initial layout designs. The designer therefore ends up being able to explore only a very limited portion of the overall design space, which usually results in sub-optimal layout design(s) being selected and implemented and ultimately unnecessarily high levels of virus transmission in the ultimate building structure.

The above problem can oftentimes be exacerbated by the non-intuitive influences that different combinations of positions and orientations of spatial elements are likely to have on virus transmissions within a building. Because designing buildings to reduce virus transmissions has become a priority only relatively recently, design strategies that are likely to reduce virus transmission can elude even seasoned designers. Consequently, a designer may initially generate and subsequently modify layout designs for a building based on unsubstantiated and ineffectual design strategies while overlooking other less intuitive designs and/or modifications that could be associated with significantly lower virus transmissions within the building.

As the foregoing illustrates, what is needed in the art are more effective techniques for generating building layouts that are designed to reduce virus transmissions.

### SUMMARY

One embodiment sets forth a computer-implemented method for generating building designs that reduce virus transmissions. In some embodiments, the method includes generating a first set of layout designs for the building based on a first set of design vectors and a baseline layout design; executing, multiple times, a stochastic multi-agent virus simulator on a first layout design included in the first set of layout designs and a first simulation configuration to generate a first set of simulation results; computing a first risk score associated with both the first layout design and a first virus based on the first set of simulation results; executing one or more evolutionary operations on the first set of design vectors based on the first risk score and at least one other risk score to generate a second set of design vectors; and generating a second set of layout designs for the building based on the second set of design vectors and the baseline layout design, wherein at least a second layout design included in the second set of layout designs reduces a transmission of the first virus relative to the first set of layout designs.

At least one technical advantage of the disclosed techniques relative to the prior art is that, with the disclosed techniques, layout designs for buildings are automatically generated based on the goal of iteratively reducing values for at least one virus transmission metric. Because the layout designs are automatically generated and optimized by CAD software when implementing the disclosed techniques, the total number of layout designs that are generated can be increased relative to what can be achieved with approaches that rely on conventional CAD software. Furthermore, with the disclosed techniques, an evolutionary algorithm is used to systematically guide the exploration of the design space in accordance with the goal of reducing virus transmission metric values. Consequently, the design space can be more thoroughly and effectively explored relative to what can be achieved with conventional CAD tools. In addition, the disclosed techniques can identify non-intuitive combinations of positions and orientations of spatial elements within a layout that reduce virus transmissions. Consequently, with the disclosed techniques, layout designs can be generated that otherwise would not be generated using conventional CAD software. These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the generative design engine of FIG. 1, according to various embodiments;

FIG. 3 is an exemplar illustration of the graphical user interface of FIG. 1, according to various embodiments; and

FIG. 4 is a flow diagram of method steps for generating layout designs for a building that reduce virus transmissions, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

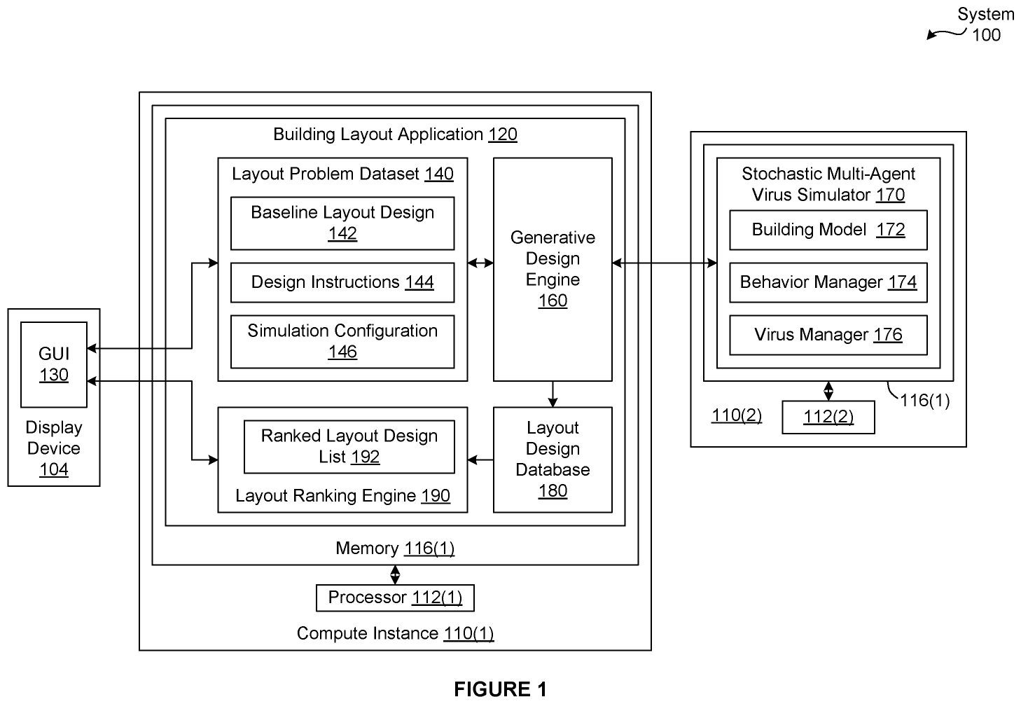

FIG. 1 is a conceptual illustration of a system 100 configured to implement one or more aspects of the various embodiments. As shown, in some embodiments, the system 100 includes, without limitation, a compute instance 110(1), a compute instance 110(2), and a display device 104. In some other embodiments, the compute instance 110(1), the compute instance 110(2), the display device 104, or any combination thereof can be omitted from the system 100. In the same or other embodiments, the system 100 can include, without limitation, any number and/or types of other compute instances, other display devices, other output devices, input/output devices, input devices, or any combination thereof. In some embodiments, the components of the system 100 can be distributed across any number of shared geographic locations and/or any number of different geographic locations and/or implemented in one or more cloud computing environments (i.e., encapsulated shared resources, software, data, etc.) in any combination.

As shown, the compute instance 110(1) includes, without limitation, a processor 112(1) and a memory 116(1), and the compute instance 110(2) includes, without limitation, a processor 112(2) and a memory 116(2). For explanatory purposes, the compute instance 110(1) and the compute instance 110(2) are also referred to herein individually as “the compute instance 110” and collectively as “the compute instances 110.” The processor 112(1) and the processor 112(2) are also referred to herein individually as “the processor 112” and collectively as “the processors 112.” The memory 116(1) and the memory 116(2) are also referred to herein individually as “the memory 116” and collectively as “the memories 116.” Each of the compute instances 110 can be implemented in a cloud computing environment, implemented as part of any other distributed computing environment, or implemented in a stand-alone fashion.

The processor 112 can be any instruction execution system, apparatus, or device capable of executing instructions. For example, the processor 112 could be a central processing unit, a graphics processing unit, a controller, a micro-controller, a state machine, or any combination thereof. The memory 116 of the compute instance 110 stores content, such as software applications and data, for use by the processor 112 of the compute instance 110. The memory 116 can be one or more of a readily available memory, such as random-access memory, read-only memory, floppy disk, hard disk, or any other form of digital storage, local or remote.

In some other embodiments, each compute instance 110 can include any number of processors 112 and any number of memories 116 in any combination. In particular, any number of the compute instances 110 (including one) and/or any number of other compute instances can provide a multiprocessing environment in any technically feasible fashion.

In some embodiments, a storage (not shown) may supplement or replace the memories 116 of the compute instance 110. The storage may include any number and type of external memories that are accessible to the processor 112 of the compute instance 110. For example, and without limitation, the storage can include a Secure Digital Card, an external Flash memory, a portable compact disc read-only memory, an optical storage device, a magnetic storage device, or any suitable combination of the foregoing.

As shown, the compute instance 110(1) is associated with the display device 104. The display device 104 can be any device that is capable of displaying an image and/or any other type of visual content. For example, the display device 104 could be, without limitation, a liquid crystal display, a light-emitting diode display, a projection display, or a plasma display panel. In some embodiments, the display device 104 is a touchscreen that is capable of displaying visual content and receiving input (e.g., from a user).

In some other embodiments, the compute instance 110(1) can be integrated with any number and/or types of other devices (e.g., the compute instance 110(2), other compute instances, input devices, output devices, input/output devices) into a user device. Some examples of user devices include, without limitation, desktop computers, laptops, smartphones, smart televisions, game consoles, and tablets.

In general, each compute instance 110 is configured to implement one or more software applications. For explanatory purposes only, each software application is described as residing in the memory 116 of a single compute instance (e.g., the compute instance 110(1) or the compute instance 110(2) and executing on the processor 112 of the single compute instances.

In some embodiments, any number of instances of any number of software applications can reside in the memory 116 and any number of other memories associated with any number of other compute instances and execute on the processor 112 of the compute instance 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the compute instance 110(1) is configured to automatically generate layout designs for buildings based on a goal of reducing virus transmission within the buildings. As described previously herein, in a conventional approach to generating layout designs for a building, a designer uses conventional CAD software to generate a variety of different 2D layout designs. The designer then typically uses heuristic-based estimation software and/or simulation software to evaluate each layout design with respect to transmission of a given target virus. The designer discards sub-optimal layout designs and uses the conventional CAD software to modify any number of the remaining layout designs based on the virus evaluations. The designer continues to evaluate newly modified layout designs, discard sub-optimal layout designs, and iteratively modify the remaining layout designs until eventually selecting one or more layout designs for subsequent design activities.

One drawback of the above approach is that effectively exploring the design space associated with a typical building layout problem using conventional CAD software is difficult, if not impossible. In that regard, initially generating and subsequently modifying layout designs for buildings via conventional CAD tools is usually very time-consuming. Accordingly, with the limited amount of time normally allocated for a building layout process, the designer usually ends up being able to explore only a very limited portion of the overall design space, which usually results in sub-optimal layout design(s) being selected and implemented and ultimately unnecessarily high levels of virus transmission in the ultimate building structure. The above problem can oftentimes be exacerbated by unsubstantiated and ineffectual design strategies used by the designer in an attempt to reduce virus transmission within buildings.

Automatically Generating Building Layouts that Reduce Virus Transmissions

To address the above problems, in some embodiments, the compute instance 110(1) includes, without limitation, a building layout application 120 that automatically generates layout designs that solve a building layout problem defined via a graphical user interface (GUI) 130 based on a goal of iteratively reducing values for at least one virus transmission metric. As persons skilled in the art will recognize, an evolutionary algorithm is a meta-heuristic for solving optimization problems that is inspired by principles of biological evolution, such as natural selection. Some examples of evolutionary algorithms are the Non-Dominated Sorting Genetic Algorithm II (NSGA-II), the Strength Pareto Evolutionary Algorithm, and the Pareto Archived Evolution Strategy (PAES).

As used herein, a “virus transmission metric” can be any type of measurement that correlates to a risk of transmission of a virus within a building. Any type (e.g., average, absolute, etc.) of value for a virus transmission metric is also referred to herein as a “virus transmission metric value.” The building layout application 120 uses a stochastic multi-agent virus simulator 170 to compute the virus transmission metric values that guide the evolutionary algorithm.

The stochastic multi-agent virus simulator 170 can be any type of stochastic multi-agent simulator for architectural designs that is capable of simulating the spread of at least one virus between multiple occupants through at least one vector of transmission. Some examples of vector of transmission are air, surfaces, and water. In the context of the stochastic multi-agent virus simulator 170, agents are models of humans within buildings. A model of a human within a building is also referred to herein as a “virtual occupant.” In some other embodiments, a virtual occupant can be any type of living creature, such as a human or a pet.

For explanatory purposes, the functionality of the building layout application 120 is described in greater detail below in the context of an exemplar evolutionary algorithm, a target office building that includes a single floor, a target virus, and a goal of reducing air risk scores and surface risk scores. As described in greater detail below, an air risk score is an average value for an air-based virus transmission metric and a surface risk score is an average value for a surface-based virus transmission metric. Also for explanatory purposes, the functionality of the stochastic multi-agent virus simulator 170 is described in greater detail below in the context of simulating both air-based transmission and surface-based transmission of a target virus using an exemplar stochastic multi-agent simulation framework for architectural designs.

Note that the techniques described herein are illustrative rather than restrictive and may be altered without departing from the broader spirit and scope of the invention. Many modifications and variations on the functionality provided by the building layout application 120 and the stochastic multi-agent virus simulator 170 will be apparent to those of ordinary skill in the art without departing from the scope and spirit of the described embodiments.

As shown, in some embodiments, the building layout application 120 resides in the memory 116(1) of the compute instance 110(1) and executes on the processor 112(1) of the compute instance 110(1). The building layout application 120 interfaces with a user via the GUI 130. In some embodiments, the building layout application 120 and a 3D design application (not shown) interact with the same user via the GUI 130. The GUI 130 can be any type of user interface that allows users to interact with one or more software applications via any number and/or types of GUI elements. The GUI 130 can be displayed in any technically feasible fashion on the display device 104.

The building layout application 120 can perform any number and/or types of operations to directly and/or indirectly display and monitor any number and/or types of interactive GUI elements and/or any number and/or types of non-interactive GUI elements within the GUI 130. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the building layout application 120 organizes GUI elements into one or more container GUI elements (e.g., panels, panes) within the GUI 130.

As shown, the building layout application 120 includes, without limitation, the layout problem dataset 140, a generative design engine 160, a layout design database 180, and a layout ranking engine 190. To initiate an automatic layout process for a building design, the building layout application 120 generates the layout problem dataset 140 based on user input received via the GUI 130. The layout problem dataset 140

As shown, in some embodiments, the building layout application 120 resides in the memory 116(1) of the compute instance 110(1) and executes on the processor 112(1) of the compute instance 110(1). The building layout application 120 interfaces with a user via the GUI 130. In some embodiments, the building layout application 120 and a 3D design application (not shown) interact with the same user via the GUI 130. The GUI 130 can be any type of user interface that allows users to interact with one or more software applications via any number and/or types of GUI elements. The GUI 130 can be displayed in any technically feasible fashion on the display device 104.

The building layout application 120 can perform any number and/or types of operations to directly and/or indirectly display and monitor any number and/or types of interactive GUI elements and/or any number and/or types of non-interactive GUI elements within the GUI 130. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the building layout application 120 organizes GUI elements into one or more container GUI elements (e.g., panels, panes) within the GUI 130.

As shown, in some embodiments, the building layout application 120 includes, without limitation, a layout problem dataset 140, a generative design engine 160, a layout design database 180, and a layout ranking engine 190. To initiate an automatic layout process for a building design, the building layout application 120 generates the layout problem dataset 140 that defines a layout problem for a target building based on user input received via the GUI 130.

As shown, the layout problem dataset 140 includes, without limitation, a baseline layout design 142, design instructions 144, and simulation configuration 146. The baseline layout design 142 specifies a building outline for the target building, a floor outline for each floor of the target building, and the positions and orientations of any number of fixed spatial elements within the building in any technically feasible fashion. Some examples of fixed spatial elements are kitchens, bathrooms, elevators, and stairs.

The design instructions 144 specify any number and/or types of flexible spatial elements that are to be placed within the target building and any amount and/or types of associated placement-related metadata in any technically feasible fashion. In some embodiments, the design instructions 144 can specify that any number (including zero) of the flexible spatial elements are flexible shared amenities. As used herein, a “flexible shared amenity” is a flexible spatial element that is to be shared among multiple neighborhoods. As used herein, “neighborhoods” refer to different discrete and non-overlapping portions of floors that are not assigned to fixed spatial elements as per the baseline layout design 142.

The simulation configuration 146 specifies any number and/or types of simulator properties, virtual occupant properties, and virus properties. For instance, in some embodiments, the simulation configuration 146 specifies a building context, a simulation duration, a time step, a grid spacing, any number and/or types of properties associated with one or more occupant groups, any number and/or types of properties associated with one or more target viruses, or any combination thereof.

Some examples of building contexts are office building, restaurant, and condominium. Some properties that can be associated with an occupant group include the number of virtual occupants in the group, an initial health status (e.g., susceptible, infected), a role with respect to behavior within the building, an entering time, a leaving time, and a mask-wearing status. For example, an occupant group could specify that four susceptible sales agents enter an office building between 8 AM and 8:15 AM and leave the office building between 5 PM and 5:30 PM. Some examples of properties associated with a target virus include one or more half-life values and a diffusion coefficient.

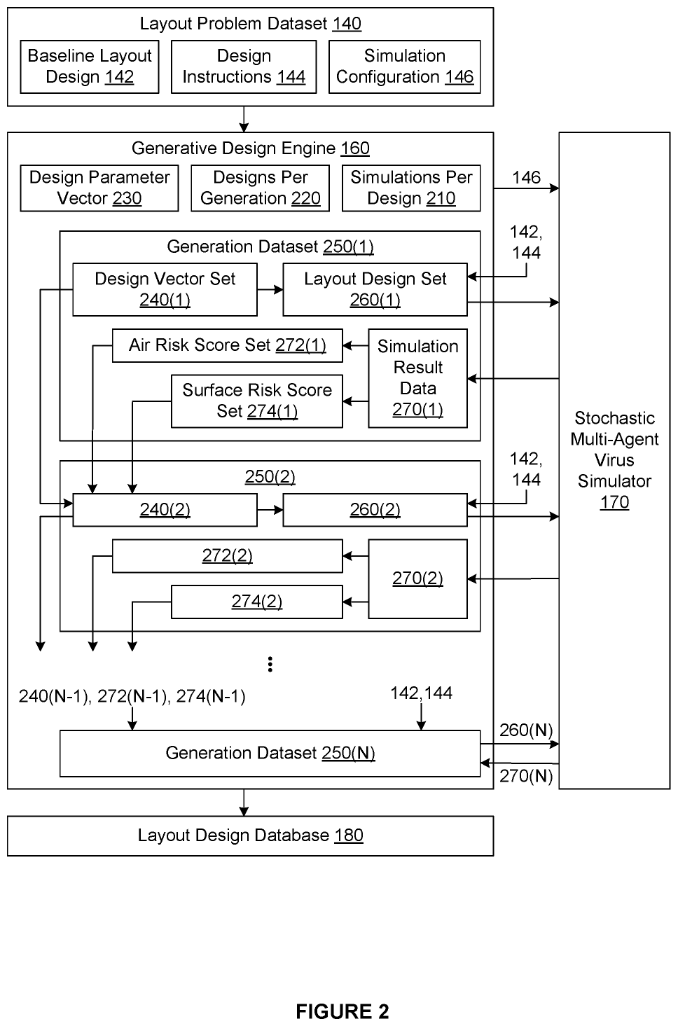

As shown, the generative design engine 160 interfaces with the stochastic multi-agent virus simulator 170 to generate the layout design database 180 based on the layout problem dataset 140. As described in greater detail below in conjunction with FIG. 2, the generative design engine 160 implements an evolutionary algorithm (not shown in FIG. 1) to generate multiple generations of layout designs based on the layout problem dataset 140 and a goal of reducing air risk scores and surface risk scores.

Notably, after generating each new generation of layout designs, the generative design engine 160 uses the stochastic multi-agent virus simulator 170 to generate a different simulation result set (not shown in FIG. 1) for each of the layout designs in the new generation. As persons skilled in the art will recognize, because the stochastic multi-agent virus simulation 170 includes stochastic aspects, the generative design engine 160 uses the stochastic multi-agent virus simulation 170 to run multiple simulations for each layout design. Accordingly, each simulation result set includes multiple different simulation results for the associated layout design. The stochastic multi-agent virus simulator 170 is described in greater detail below.

For each layout design in the new generation, the generative design engine 160 computes an air risk score and a surface risk score based on the associated simulation result set. The generative design engine 160 stores the new generation of layout designs, the associated air risk scores, the associated surface risk scores, and the associated simulation result sets in the layout design database 180.

If the generative design engine 160 determines that the new generation of layout designs is not the final generation layout designs, then the generative design engine 160 executes one or more evolutionary operations on the new generation of layout designs based on the air risk scores and the surface risk scores to generate a next generation of layout designs. If, however, the generative design engine 160 determines that the new generation of layout designs is the final generation of layout designs, then the generative design engine 160 finishes executing,

Subsequently, the building layout application 120 displays an initial version of a result pane (not shown in FIG. 1) within the GUI 130. The result pane includes any number and/or types of interactive GUI elements and any number and/or types of non-iterative GUI elements that can be organized in any technically feasible fashion. The initial version of the result pane enables a user to specify via the GUI 130 a ranking criterion (not shown) and optionally any number of filtering criteria (not shown) for the layout designs included in the layout design database 180. Some examples of ranking criteria are air risk score, surface risk score, and the sum of air risk score and surface risk score. Some examples of filtering criteria include less than a maximum air risk score, less than a maximum surface risk score, and only the final generation of layout designs.

As shown, the layout ranking engine 190 ranks and optionally filters the layout designs included in the layout design database 180 based on the ranking criterion and any optional filtering criteria, respectively, to generate a ranked layout design list 192. More generally, the layout ranking engine 190 can execute any number and/or types of ranking operations and optionally any number and/or types of filtering operations on any portion of the layout designs included in the layout design database 180 based on any number and/or types of criteria and any amount and/or types of associated data to generate the ranked layout design list 192. The ranked layout design list 192 includes any number of the layout designs stored in the layout design database 180. The layout ranking engine 190 then displays at least a portion of the ranked layout design list 192 and optionally any amount and/or types of associated data within the GUI 130.

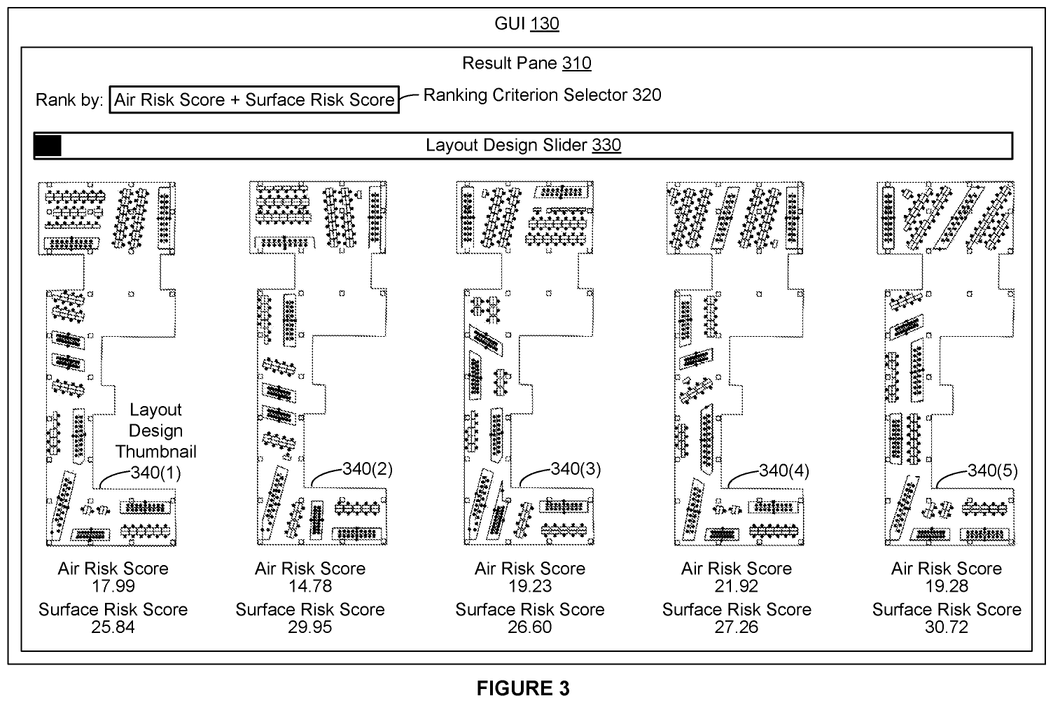

The layout ranking engine 190 can display at least a portion of the ranked layout design list 192 and optionally any amount and/or types of associated data within the GUI 130 in any technically feasible fashion. As described in greater detail below in conjunction with FIG. 3, in some embodiments, the layout ranking engine 190 updates the result pane displayed within the GUI 130 to reflect the ranked layout design list 192 and any amount and/or types of associated data (e.g., air risk scores, surface risk scores).

Notably, if the user subsequently modifies the ranking criterion and/or the filtering criterion via the result pane, the layout ranking engine 190 regenerates the ranked layout design list 192 and updates the result pane accordingly. The user can select via the result pane one or more of the layout designs included in the ranked layout design list 192 for subsequent design activities.

As shown, the stochastic multi-agent virus simulator 170 resides in the memory 116(2) of the compute instance 110(2) and executes on the processor 112(2) of the compute instance 110(2). The stochastic multi-agent virus simulator 170 is a stochastic multi-agent simulator for architectural designs that simulates the amount of viruses transmitted between occupants within buildings. In particular, the stochastic multi-agent virus simulator 170 automatically generates relevant behaviors for virtual occupants in relation to a building and simulates both air-based and surface-based transmission of one or more target viruses within the building.

As described in greater detail below in conjunction with FIG. 2, the inputs to the multi-agent virus simulator 170 are a layout design and a simulation configuration. The output of the stochastic multi-agent virus simulator 170 is a simulation result associated with both the layout design and the simulation configuration. Each simulation configuration includes any amount and/or types of data relevant to executing a multi-agent virus simulation based on a different combination of simulation, virtual occupants, and virus properties.

In operation, executing the stochastic multi-agent virus simulator 170 on a given layout design and a given simulation configuration causes the stochastic multi-agent virus simulator 170 to simulate the spread of one or more target viruses between multiple occupants within the building in accordance with the given layout design and the given simulation configuration through both air and surfaces.

As shown, the stochastic multi-agent virus simulator 170 includes, without limitation, a building model 172, a behavior manager 174, and a virus manager 176. The building model 172 is a 3D model of the building. The stochastic multi-agent virus simulator 170 generates the building model 172 based on a layout design and optionally any amount and/or types of data included in a simulation configuration.

The behavior manager 174 implements any number and/or types of stochastic techniques for modeling any number and/or types of behaviors for each of the virtual occupants. Some examples of stochastic techniques for modeling behaviors of virtual occupants include Markov chains, logistic regression, and survival analysis. In particular, the behavior manager 174 models context-related behaviors and contagion-related behaviors. Some examples of context-related behaviors are chatting in a meeting room, working at a personal desk, and eating in a break room. Some examples of contagion-related behaviors are breathing, sneezing, coughing, talking, surface-touching, face-touching, hand-sanitizing, surface cleaning, and eating.

The virus manager 176 models the air-based transmission and the surface-based transmission of a target virus. For air-based transmission, the virus manager 176 tracks the contamination values of different grid cells of air within the building over time based on occupant behaviors, air-based diffusion, circulation, and decay. In particular, the virus manager 176 emulates the transfer of virus particles between each occupant's lungs and the surrounding grid cells of air in response to respiratory behaviors (e.g., breathing sneezing, coughing, talking),

For surface-based transmission, the virus manager 176 tracks the contamination values of different surfaces within the building over time based on occupant behaviors and material-based decay. More precisely, the virus manager 176 emulates changes in contamination in response to touch-related occupant behaviors (e.g., surface-touching, face-touching, hand-sanitizing, surface cleaning, and eating.

Each simulation result includes any amount and/or types of spatial-based data and time-based data associated with transmission of any number of viruses in any type of building as per an associated layout design and an associated simulation configuration. For instance, in some embodiments, each simulation result includes spatial-based data and time-based data associated with both air-based transmission and surface-based transmission of a target virus within a target building.

Note that the techniques described herein are illustrative rather than restrictive and can be altered without departing from the broader spirit and scope of the invention. Many modifications and variations on the functionality of the building layout application 120, the generative design engine 160, the layout ranking engine 190, the GUI 130, the stochastic multi-agent virus simulator 170, the building model 172, the behavior manager 174, the virus manager 176, and the exemplar evolutionary algorithm as described herein will be apparent to those of ordinary skill in the art without departing from the scope and spirit of the described embodiments and techniques. Further, in various embodiments, any number of the techniques disclosed herein may be implemented while other techniques may be omitted in any technically feasible fashion.

For instance, in some embodiments, the building layout application 120 can implement any number and/or types of evolutionary algorithms to generate layout designs for any type of building that includes any number of floors. In the same or other embodiments, the generative design engine 160 can compute values for any number and/or types of metrics that correlate to transmission of any number and/or types of viruses in order to guide the evolutionary algorithm(s). In the same or other embodiments, the generative design engine 160 can execute each layout design multiple times over any number of different simulation configurations. In some embodiments, the stochastic multi-agent virus simulator 170 can simulate transmission of any number and/or types of viruses through at least one vector of transmission and between any number and/or types of occupants within any type of building that includes any number of floors in any technically feasible fashion.

Similarly, many modifications and variations on the layout problem dataset 140, the baseline layout design 142, the design instructions 144, the simulation configuration 146, the layout design database 180, and the ranked layout design list 192 will be apparent to those of ordinary skill in the art without departing from the scope and spirit of the described embodiments. For instance, in some embodiments, the layout problem dataset 140 specifies multiple simulation configurations.

It will be appreciated that the system 100 shown herein is illustrative and that variations and modifications are possible. For example, the functionality provided by the building layout application 120, the generative design engine 160, the layout ranking engine 190, the stochastic multi-agent virus simulator 170, the building model 172, the behavior manager 174, the virus manager 176, the exemplar evolutionary algorithm, or any combination thereof as described herein can be integrated into or distributed across any number and/or types of software applications (including one) that execute on any number of processors of any number of compute instances included in the system 100. Further, the connection topology between the various units in FIG. 1 can be modified as desired.

### Automatically Exploring a Design Space for a Building Layout Problem Based on Virus Transmission Metrics

FIG. 2 is a more detailed illustration of the generative design engine 160 of FIG. 1, according to various embodiments. As described previously herein, in some embodiments, the generative design engine 160 implements an exemplar evolutionary algorithm to iteratively generate layout designs for a target building based on the layout problem dataset 140 and a goal of reducing air risk scores and surface risk scores associated with a target virus.

As described previously herein in conjunction with FIG. 1, the layout problem dataset 140 defines a layout design problem. The layout problem dataset 140 includes the baseline layout design 142, the design instructions 144, and the simulation configuration 146. In some embodiments, the baseline layout design 142 specifies a building outline for a target building that has a single floor, a floor outline, and the positions and orientations of any number of fixed spatial elements within the target building. The design instructions 144 specifies any number and/or types of flexible shared amenities and/or any number and/or types of other flexible spatial elements that are to be positioned and oriented within the target building. The simulation configuration 146 specifies, without limitation, any number and/or types of simulator properties, any number and/or types of virtual occupant properties that are each associated with any number of virtual occupants, and any number and/or types of virus properties associated with the target virus.

As shown, in some embodiments, the generative design engine 160 includes a simulations per design 210, a designs per generation 220, a design parameter vector 230, and a generation dataset 250(1)—a generation dataset 250(N), where N can be any positive integer greater than 2. In some other embodiments, the total number of generation datasets can be 2.

The simulations per design 210 specifies the total number of times (e.g., fifty) that the generative design engine 160 is to execute the stochastic multi-agent virus simulator 170 on each layout design and the simulation configuration 146. The designs per generation 220 specifies the total number of layout designs that are to be included in each generation of layout designs. The generative design engine 160 can determine the simulations per design 210 and the designs per generation 220 in any technically feasible fashion. For instance, in some embodiments, default values for the simulations per design 210 and the designs per generation 220 are hard-coded. In the same or other embodiments, the generative design engine 160 can override a default value for the simulations per design 210 and/or a default value for the designs per generation 220 based on user input received via the GUI 130.

The design parameter vector 230 includes any number of parameters such that different combinations of values for the parameters define different layout designs. The generative design engine 160 can determine the design parameter vector 230 in any technically feasible fashion. In some embodiments, the generative design engine 160 determines a total number of neighborhoods (not shown) based on the total number of flexible shared amenities specified in the design instructions 144. More precisely, the generative design engine 160 sets the total number of neighborhoods equal to the total number of flexible shared amenities.

The generative design engine 160 then generates the design parameter vector that includes three parameters for each of the neighborhoods. As described in greater detail below, the three parameters for each neighborhood are a spine parameter, a spine perpendicular parameter, and an amenity edge parameter. To define a new layout design, the generative design engine 160 generates a new design vector that includes a different real value from 0.0 through 1.0 for each parameter in the design parameter vector.

As described in greater detail below, the generative design engine 160 implements an exemplar evolutionary algorithm to iteratively generate different generations of design vectors based on a goal of reducing air risk scores and surface risk scores. For each design vector, the generative design engine 160 automatically generates a corresponding layout design, uses the stochastic multi-agent virus simulator 170 to generate an associated simulation result set, and computes an air risk score and a surface risk score based on the associated simulation result set.

The generation dataset 250(1)—the generation dataset 250(N) correspond to a first generation of layout design vectors through an N^{th} generation of layout design vectors. The first generation of layout design vectors through the N^{th} generation of layout design vectors are also referred to herein as the first generation of layout designs through the N^{th} generation of layout designs, respectively. Further, the first generation of layout design vectors is also referred to herein as an initial generation of layout design vectors and an initial generation of layout designs.

As shown, the generation dataset 250(1) includes, without limitation, a design vector set 240(1), a layout design set 260(1), simulation result data 270(1), an air risk score set 272(1), and a surface risk score set 274(1). As also shown, the generation dataset 250(2) includes, without limitation, a design vector set 240(2), a layout design set 260(2), simulation result data 270(2), an air risk score set 272(2), and a surface risk score set 274(2). Although not explicitly shown, for an integer x from 3 through N, the generation dataset 250(x) includes, without limitation, a design vector set 240(x), a layout design set 260(x), simulation result data 270(x), an air risk score set 272(x), and a surface risk score set 274(x). As per the exemplar evolutionary algorithm, the generation design engine 160 sequentially and iteratively generates the generation dataset 250(1)—the generation dataset 250(N).

During a first iteration, the generative design engine 160 generates and stores (in the layout design database 180) the generation dataset 250(1). To initiate the first iteration, the generative design engine 160 randomly generates the design vector set 240(1). The design vector set 240(1) includes M different design vectors, where M denotes the designs per generation 220. Each of the design vectors included in the design vector set 240(1) includes a different randomly-generated combination of values (from 0.0 through 1.0) for the parameters included in the design parameter vector 230. More precisely, in some embodiments, the generative design engine 160 randomly assigns a real value from 0.0 through 1.0 to each parameter included in the design parameter vector 230 to generate each design vector included in the design vector set 240(1).

As shown, the generative design engine 160 generates the layout design set 260(1) based on the baseline layout design 142, the design instructions 144, and the design vector set 240(1). The layout design set 260(1) includes M different layout designs for an associated building, where each layout design corresponds to a different design vector included in the design vector set 240(1). A layout design for a building is also referred to herein as a “building layout design.” As used herein, a “building layout design” is a building design that specifies an arrangement or layout of any number of spatial elements within a building.

In general, to generate a layout design based on the baseline layout design 142, the design instructions 144, and a given design vector, the generative design engine 160 partitions the baseline layout design 142 into multiple neighborhoods based on the given design vector. The generative design engine 160 can determine the multiple neighborhoods in any technically feasible fashion.

In some embodiments, to determine the multiple neighborhoods, the generative design engine 160 generates a linear spline over the baseline layout design 142. The generative design engine 160 distributes seeds representing the centers of the neighborhoods evenly along the linear spline. For each neighborhood, the generative design engine 160 moves the associated seed from the initial point along the linear spline for a distance corresponding to the value for the associated spine parameter. For each neighborhood, the generative design engine 160 subsequently moves the associated seed in a perpendicular direction away from the linear spine for a distance corresponding to the value for the associated spline perpendicular parameter.

The generative design engine 160 then determines a position and an orientation for each flexible shared amenity based on the first design vector in any technically feasible fashion. For instance, in some embodiments, the generative design engine 160 selects an edge of each neighborhood based on the value of the associated amenity edge parameter. The generative design engine 160 then places an icon representing a flexible shared amenity along each selected edge.

Subsequently, the generative design engine 160 implements any number and/or types of deterministic algorithms (e.g., a greedy fill algorithm) to distribute icons representing any remaining flexible spatial elements across the neighborhoods. The resulting layout design is a version of the baseline layout design 142 that is enhanced to specify the positions and orientations of the flexible spatial elements.

As shown, the generative design engine 160 uses the stochastic multi-agent virus simulator 170 to generate the simulation result data 270(1) based on the simulation configuration 146 and the layout design set 260(1). The simulation result data 270(1) includes M different simulation result sets, where each simulation result set is associated with a different layout design included in the layout design set 260(1) and therefore a different design vector included in the design vector set 240(1). Each simulation result set includes S different simulation results, where S denotes the simulations per design 210. To generate the simulation result set associated with each layout design, the generative design engine 160 executes the stochastic multi-agent virus simulator 170 on the layout design and the simulation configuration 146 a total of S different times.

Each simulation result includes, without limitation, any amount of spatial-based data and time-based data associated with both air-based transmission and surface-based transmission of the target virus within the target building. In some embodiments, each simulation result specifies air-based contamination values and surface-based contamination values for each susceptible occupant and each grid cell at the granularity of the time step over the simulation duration. An air-based contamination value associated with both a susceptible occupant and a time step estimates the total amount of virus particles that the susceptible occupant has accumulated by inhaling contaminated air from the beginning of the simulation to the time step. A surface-based contamination value associated with both a susceptible occupant and a time step estimates the total amount of virus particles that the susceptible occupant has accumulated via surface interactions and face-touching from beginning of the simulation to the time step.

As shown, the generative design engine 160 computes the air risk score set 272(1) and the surface risk score set 274(1) based on the simulation result data 270(1). The air risk score set 272(1) includes a different air risk score for each layout design included in the layout design set 260(1) and therefore for each design vector included in the design vector set 240(1). The surface risk score set 274(1) includes a different surface risk score for each layout design included in the layout design set 260(1) and therefore for each design vector included in the design vector set 240(1).

As described previously herein in conjunction with FIG. 1, each air risk score is an average value for an air-based transmission metric and each surface risk score is an average value for a surface-based transmission metric. The air-based transmission metric and the surface-based transmission metric can quantify any number and/or aspects associated with transmission of the target virus in any technically feasible fashion. In some embodiments, the air-based transmission metric and the surface-based transmission metric quantify the magnitude of virus transmission that occurs via air-based routes and surface-based routes, respectively, over the simulation duration.

More precisely, the air-based transmission metric and the surface-based transmission metric estimate the total amount of virus particles that would likely spread via air and surfaces, respectively from a single infected occupant to all susceptible occupants over the simulation duration. In some embodiments, the generative design engine 160 sets a value for the air-based transmission metric for a simulation result equal to the sum of a subset of the air-based contamination values included in the simulation result that are associated with susceptible occupants and the final time step divided by the total number of susceptible occupants. Similarly, the generative design engine 160 sets a value for the surface-based transmission metric for a given simulation result equal to the sum of a subset of the surface-based contamination values included in the simulation result that are associated with susceptible occupants and the final time step divided by the total number of susceptible occupants.

For explanatory purposes, a value for the air-based transmission metric is also referred to herein as an “air-based transmission metric value.” Similarly, a value for the surface-based transmission metric is also referred to herein as a “surface-based transmission metric value.” In general, after generating each simulation result set, the generative design engine 160 sets the air risk score for the associated layout design equal to the average of the S air-based transmission metric values for the S simulation results included in the simulation result set. And the generative design engine 160 sets the surface risk score for the associated layout design equal to the average of the S surface-based transmission metric values for the S simulation results included in the simulation result set.

To complete the first iteration of the evolutionary algorithm, the generative design engine 160 stores the design vector set 240(1), the layout design set 260(1), the simulation result data 270(1), the air risk score set 272(1), and the surface risk score set 274(1) in the layout design database 180.

As shown, during a second iteration, the generative design engine 160 generates and stores (in the layout design database 180) the generation dataset 250(2). To initiate the second iteration, the generative design engine 160 generates the design vector set 240(2) based on the design vector set 240(1), the air risk score set 272(1), the surface risk score set 274(1), and the layout problem dataset 140. The generative design engine 160 implements a selection stage, a crossover stage, a mutation stage, and optionally any number and/or types of other evolutionary stages to generate the design vector set 240(2) based on the design vector set 240(1), the air risk score set 272(1), and the surface risk score set 274(1).

In the selection stage, the generative design engine 160 designates a subset of the design vector set 240(1) as parent design vectors for the second generation based, at least in part, on the air risk score set 272(1) and the surface risk score set 274(1). The generative design engine 160 can implement any number and/or types of selection operations to select the parent design vectors. Some examples of parent selection operations are fitness proportionate selection operations, rank selection operations, tournament selection operations, stochastic universal sampling operations, and Boltzmann selection operations. In general, the overall probability of selecting a design vector as a parent design vector increases as the associated air risk score and the associated surface risk score increase.

Optionally, in the selection stage, the generative design engine 160 also implements any number and/or types of elitist selection operations to pass-through a subset of the design vector set 240(1) having the highest fitness unchanged to the design vector set 240(2). The fitness of a design vector correlates to both the associated air risk score and the surface risk score.

In the crossover stage, the generative design engine 160 combines different pairs of the parent design vectors to generate child design vectors and then adds the child design vectors to the design vector set 240(2). The generative design engine 160 can execute any number and/or types of crossover operations on a pair of parent design vectors to generate one or more child design vectors. Some examples of crossover operations are one-point crossover, k-point crossover, discrete recombination, and intermediate recombination.

In the mutation stage, the generative design engine 160 randomly or pseudo-randomly perturbs any number of the parent design vectors while taking into account the valid value range to generate mutated design vectors and then adds the mutated design vectors to the design vector set 240(2). As described previously herein, the valid value range for each of the values in a design vector is from 0.0 through 1.0. The generative design engine 160 can execute any number and/or types of mutation operations on a parent design vector to generate a mutated design vector. Some examples of mutation operations are uniform mutation, non-uniform mutation, and Gaussian mutation.

The generative design engine 160 applies the same techniques described previously herein in conjunction with the generation dataset 250(1) to generate the layout design set 260(2), the simulation result data 270(2), the air risk score set 272(2), and the surface risk score set 274(2) based on the design vector set 240(2) and the layout problem dataset 140. To complete the second iteration of the evolutionary algorithm, the generative design engine 160 stores the design vector set 240(2), the layout design set 260(2), the simulation result data 270(2), the air risk score set 272(2), and the surface risk score set 274(2) in the layout design database 180.

To initiate each subsequent iteration, for an integer x from 3 through N, the generative design engine 160 applies the same techniques described previously herein in conjunction with the design vector set 240(2) to generate the design vector set 240(x). More precisely, the generative design engine 160 implements a selection stage, a crossover stage, a mutation stage, and optionally any number and/or types of other evolutionary stages to generate the design vector set 240(x) based on the design vector set 240(x-1), the air risk score set 272(x-1), and the surface risk score set 274(x-1).

The generative design engine 160 then applies the same techniques described previously herein in conjunction with the generation dataset 250(1) to generate the layout design set 260(x), the simulation result data 270(x), the air risk score set 272(x), and the surface risk score set 274(x) based on the design vector set 240(x) and the layout problem dataset 140. To complete the x^{th} iteration of the evolutionary algorithm, the generative design engine 160 stores the design vector set 240(x), the layout design set 260(x), the simulation result data 270(x), the air risk score set 272(x), and the surface risk score set 274(x) in the layout design database 180.

The generative design engine 160 continues to iteratively generate new generation datasets associated with subsequent generations until the generative design engine 160 determines that the most recent generation is a last generation. The generative design engine 160 can determine that the most recent generation is a last generation based on any number and/or types of criteria. For instance, in some embodiments, the generative design engine 160 determines that the most recent generation is the last generation based on a maximum number of iterations. As shown, the generative design engine 160 determines that the generation associated with the generation dataset 250(N) is the last generation based on a value of N for the maximum number of iterations.

FIG. 3 is an exemplar illustration of the GUI 130 of FIG. 1, according to various embodiments. FIG. 3 depicts the GUI 130 at a point-in-time after the building layout application 120 updates a result pane 310 displayed within the GUI 130 to reflect the ranked layout design list 192. The result pane 310 can include any number and/or types of interactive GUI elements and any number and/or types of non-iterative GUI elements that can be organized in any technically feasible fashion.

The result pane 310 enables the user to specify a ranking criterion, explore the layout designs included in the ranked layout design list 192, and select or otherwise designate one or more of the layout designs for subsequent design activities. As described previously herein in conjunction with FIG. 1, the layout ranking engine 190 uses the ranking criterion to generate and optionally re-generate the ranked layout design list 192. In some other embodiments, the result pane 310 can enable the user to specify any number and/or types of additional criteria (e.g., a filtering criterion) that the layout ranking engine 190 can use to generate the ranked layout design list 192.

For explanatory purposes, the result pane 310 is depicted and described herein in the context of the layout problem dataset 140 that defines an exemplar building layout problem. The exemplar layout design problem is to position and orient eight meeting rooms and one hundred desks within a target office building that has a single floor while reducing air-based transmission and surface-based transmission of a target virus. Accordingly, the baseline layout design 142 specifies a building outline for the target office building, a floor outline, and the positions and orientations of any number of fixed spatial elements within the target office building.

The design instructions 144 specify that the flexible spatial elements to be positioned and oriented within the target office building include eight meeting rooms and one hundred desks, where the eight meeting rooms are designated as flexible shared amenities. The simulation configuration 146 specifies, without limitation, a building context of office, a simulation duration of two hours, a time step, a spatial grid spacing, eight virtual occupants that each has an initial health status of infected, thirty-two virtual occupants that each has an initial health status of susceptible, half-life values for the target virus in air and on surfaces of various materials, and a diffusion coefficient for the target virus.

As shown, the result pane 310 includes a ranking criterion selector 320, a layout design slider 330, and a layout design thumbnail 340(1)—a layout design thumbnail 340(4). The ranking criterion selector 320 enables the user to select the ranking criterion. In some embodiments, the ranking criterion selector 320 is an interactive GUI element that enables the user to select air risk score, surface risk score, or air risk score+surface risk score as the ranking criterion.

As shown, the ranking criterion selector 320 specifies “air risk score+surface risk score” as the ranking criterion. For explanatory purposes, a sum of an air risk score for a design layout and a surface risk score for the design layout is also referred to herein as a “total risk score” for the design layout. Accordingly, the ranked layout design list 192 includes any number of layout designs that are ordered from lowest total risk score to highest total risk score.

The layout design slider 330 is an interactive GUI element that enables the user to scroll through layout design thumbnails representing the layout designs included in the ranked layout design list 192 in accordance with the ranked order. More precisely, because the ranking criterion is the total risk score, the leftmost position and the rightmost position of the layout design slider 330 correspond to the layout designs included in the ranked layout design list 192 associated with the lowest total risk score and the highest total risk score, respectively.

At the point-in-time depicted in FIG. 3, the user has positioned the layout design slider 330 such that the layout ranking engine 190 displays (within the result pane 310) the layout design thumbnail 340(1)—the layout design thumbnail 340(5) representing the five highest ranked layout designs included in the ranked layout design list 192. Each of the layout design thumbnail 340(1)—the layout design thumbnail 340(5) represents a different layout design, where each layout design is a different version of the baseline layout design 142 that is augmented to specify a different combination of positions and orientations of eight meeting rooms and one hundred desks. Within each of the layout design thumbnail 340(1)—the layout design thumbnail 340(5), each relatively large rectangle encircling multiple solid dots is an icon representing a different meeting room and each relatively small rectangle abutting a single dot is an icon representing one or more desks.

As shown, the layout design thumbnail 340(1) represents a layout design that is associated with an air risk score of 17.99 and a surface risk score of 25.84 and therefore a total risk score of 43.83. The layout design thumbnail 340(2) represents a layout design that is associated with an air risk score of 14.78 and a surface risk score of 29.95 and therefore a total risk score of 44.73. The layout design thumbnail 340(3) represents a layout design that is associated with an air risk score of 19.23 and a surface risk score of 26.60 and therefore a total risk score of 45.83. The layout design thumbnail 340(4) represents a layout design that is associated with an air risk score of 21.92 and a surface layout risk score of 27.26 and therefore a total risk score of 49.18. The layout design thumbnail 340(5) represents a layout design that is associated with an air risk score of 19.28 and a surface risk score of 30.72 and therefore a total risk score of 50.00.

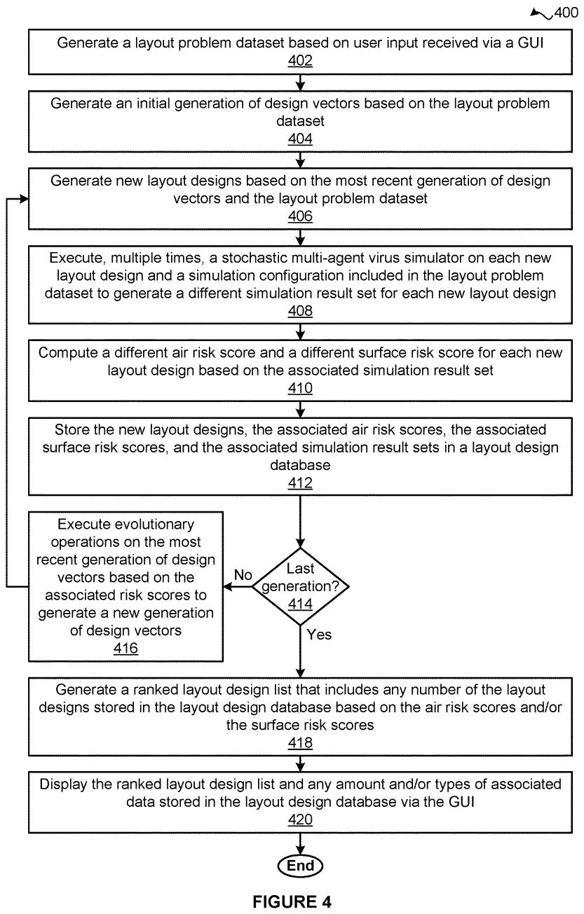

FIG. 4 is a flow diagram of method steps for generating layout designs for a building that reduce virus transmissions, according to various embodiments. Although the method steps are described with reference to the systems of FIGS. 1-3, persons skilled in the art will understand that any system configured to implement the method steps, in any order, falls within the scope of the embodiments.

As shown, a method 400 begins at step 402, where the building layout application 120 generates a layout problem dataset based on data received via a GUI. At step 404, the generative design engine 160 generates an initial generation of design vectors based on the layout problem dataset. At the end of step 404, the initial generation of design vectors is also the most recent generation of design vectors.

At step 406, the generative design engine 160 generates new layout designs based on the most recent generation of design vectors and the layout problem dataset. At step 408, the generative design engine 160 executes, multiple times, the stochastic multi-agent virus simulator 170 on each new layout design and a simulation configuration included in the layout problem dataset to generate a different simulation result set for each new layout design. At step 410, the generative design engine 160 computes a different air risk score and a different surface risk score for each new layout design based on the associated simulation result set.

At step 412, the generative design engine 160 stores the new layout designs, the associated air risk scores, the associated surface risk scores, and the associated simulation result sets in layout design database 180. At step 412, the generative design engine 160 determines whether the most recent generation of design vectors is the last generation of design vectors.

If, at step 414, the generative design engine 160 determines that the most recent generation of design vectors is not the last generation of design vectors, then the method 400 proceeds to step 416. At step 416, the generative design engine 160 executes evolutionary operations on the most recent generation of design vectors based on the associated risk scores to generate a new generation of design vectors. The method 400 then returns to step 406, where the generative design engine 160 generates new layout designs based on the most recent generation of design vectors and the definition of the building layout problem.

If, however, at step 414, the generative design engine 160 determines that the most recent generation of design vectors is the last generation of design vectors, then the method 400 proceeds directly to step 418. At step 418, the layout ranking engine 190 generates a ranked layout design list that includes any number of the layout designs stored in the layout design database 180 based on the air risk scores and/or the surface risk scores

At step 420, the building layout application 120 displays the ranked layout design list and any amount and/or types of associated data stored in the layout design database 180 via the GUI. One or more layout designs can be selected from the sorted layout design list via the GUI for subsequent design activities. The method 400 then terminates.

In sum, the disclosed techniques can be used to account for transmission of viruses between occupants of a building while automatically generating layout designs for the building. In some embodiments, a building layout application determines a layout problem dataset based on user input received via a GUI. The layout problem dataset includes a baseline layout design, design instructions, and a simulation configuration. The design instructions specify any number of flexible design elements that are to be arranged within the target building. The simulation configuration specifies any number and/or types of simulation properties, any number and/or types of occupant properties, and any number and/or types of virus properties associated with a target virus.

The building layout application implements an evolutionary algorithm to iteratively generate multiple generations of layout designs based on the layout problem dataset and a goal of reducing air risk scores and surface risk scores that are associated with the target virus. Notably, during each iteration, the building layout application uses a stochastic multi-agent virus simulator to generate a different simulation result set for each of the layout designs in the current generation of layout designs. The building layout application computes both an air risk score and a surface risk score for each layout design in the current generation of layout designs based on the associated simulation result set.

The building layout application ranks the layout designs across all generations of layout designs based on a ranking criterion (specified by the user via the GUI) to generate a ranked layout design list. The building layout application displays within the GUI the ranked layout design list, the associated air risk scores, and the associated surface risk scores. The user can select via the GUI any number of the layout designs from the ranked layout design list for subsequent design activities.

At least one technical advantage of the disclosed techniques relative to the prior art is that, with the disclosed techniques, layout designs for buildings are automatically generated based on the goal of iteratively reducing values for at least one virus transmission metric. Because the layout designs are automatically generated and optimized by CAD software when implementing the disclosed techniques, the total number of layout designs that are generated can be increased relative to what can be achieved with approaches that rely on conventional CAD software. Furthermore, with the disclosed techniques, an evolutionary algorithm is used to systematically guide the exploration of the design space in accordance with the goal of reducing virus transmission metric values. Consequently, the design space can be more thoroughly and effectively explored relative to what can be achieved with conventional CAD tools. In addition, the disclosed techniques can identify non-intuitive combinations of positions and orientations of spatial elements within a layout that reduce virus transmissions. Consequently, with the disclosed techniques, layout designs can be generated that otherwise would not be generated using conventional CAD software. These technical advantages provide one or more technological improvements over prior art approaches.

1. In some embodiments, a computer-implemented method for generating building designs that reduce virus transmissions comprises generating a first plurality of layout designs for a building based on a first plurality of design vectors and a baseline layout design; executing, multiple times, a stochastic multi-agent virus simulator on a first layout design included in the first plurality of layout designs and a first simulation configuration to generate a first plurality of simulation results; computing a first risk score associated with both the first layout design and a first virus based on the first plurality of simulation results; executing one or more evolutionary operations on the first plurality of design vectors based on the first risk score and at least one other risk score to generate a second plurality of design vectors; and generating a second plurality of layout designs for the building based on the second plurality of design vectors and the baseline layout design, wherein at least a second layout design included in the second plurality of layout designs reduces a transmission of the first virus relative to the first plurality of layout designs.

2. The computer-implemented method of clause 1, wherein the at least one other risk score includes a second risk score associated with both a second layout design included in the first plurality of layout designs and the first virus.

3. The computer-implemented method of clauses 1 or 2, wherein the first simulation configuration includes at least one of a simulation duration, a time step, a grid spacing, a plurality of initial health statuses, a plurality of mask-wearing statuses, one or more half-life values, or a diffusion coefficient.

4. The computer-implemented method of any of clauses 1-3, wherein computing the first risk score comprises dividing a sum of a subset of air-based contamination values included in the first plurality of simulation results by a total number of virtual occupants having an initial health status of susceptible.

5. The computer-implemented method of any of clauses 1-4, wherein executing, multiple times, the stochastic multi-agent virus simulator on the first layout design and the first simulation configuration causes the stochastic multi-agent virus simulator to simulate, multiple times, a spread of the first virus between multiple occupants in accordance with the first layout design.

6. The computer-implemented method of any of clauses 1-5, wherein the one or more evolutionary operations include at least one of a parent selection operation, an elitist selection operation, a crossover operation, or a mutation operation.

7. The computer-implemented method of any of clauses 1-6, further comprising randomly assigning a real value from 0.0 through 1.0 to each parameter included in a plurality of parameters to generate a first design vector included in the first plurality of design vectors.

8. The computer-implemented method of any of clauses 1-7, wherein generating the first plurality of layout designs comprises partitioning the first layout design into a plurality of neighborhoods based on a first design vector included in the first plurality of design vectors; and determining a first position and a first orientation of a first icon representing a first flexible spatial element that is shared among the plurality of neighborhoods based on the first design vector.

9. The computer-implemented method of any of clauses 1-8, wherein generating the first plurality of layout designs further comprises distributing a plurality of icons representing a plurality of flexible spatial elements across the plurality of neighborhoods.

10. The computer-implemented method of any of clauses 1-9, further comprising performing at least one ranking operation on at least the second plurality of layout designs based on a second plurality of risk scores associated with both the second plurality of layout designs and the first virus to generate a ranked layout design list; and displaying at least a portion of the ranked layout design list within a graphical user interface.

11. In some embodiments, one or more non-transitory computer readable media include instructions that, when executed by one or more processors, cause the one or more processors to generate building designs that reduce virus transmissions by performing the steps of generating a first plurality of layout designs for a building based on a first plurality of design vectors and a baseline layout design; executing, multiple times, a stochastic multi-agent virus simulator on a first layout design included in the first plurality of layout designs and a first simulation configuration to generate a first plurality of simulation results; computing a first risk score associated with both the first layout design and a first virus based on the first plurality of simulation results; executing one or more evolutionary operations on the first plurality of design vectors based on the first risk score and at least one other risk score to generate a second plurality of design vectors; and generating a second plurality of layout designs for the building based on the second plurality of design vectors and the baseline layout design, wherein at least a second layout design included in the second plurality of layout designs reduces a transmission of the first virus relative to the first plurality of layout designs.

12. The one or more non-transitory computer readable media of clause 11, wherein the at least one other risk score includes a second risk score associated with both the first layout design and a second virus.

13. The one or more non-transitory computer readable media of clauses 11 or 12, wherein the first simulation configuration includes at least one of a simulation duration, a time step, a grid spacing, a plurality of initial health statuses, a plurality of mask-wearing statuses, one or more half-life values, or a diffusion coefficient.

14. The one or more non-transitory computer readable media of any of clauses 11-13, wherein computing the first risk score comprises dividing a sum of a subset of surface-based contamination values included in the first plurality of simulation results by a total number of virtual occupants having an initial health status of susceptible.

15. The one or more non-transitory computer readable media of any of clauses 11-14, wherein the baseline layout design includes a building outline, one or more floor outlines, a plurality of positions associated with a plurality of fixed spatial elements, and a plurality of orientations associated with the plurality of fixed spatial elements.

16. The one or more non-transitory computer readable media of any of clauses 11-15, wherein the one or more evolutionary operations include at least one of a parent selection operation, an elitist selection operation, a crossover operation, or a mutation operation.

17. The one or more non-transitory computer readable media of any of clauses 11-16, further comprising randomly assigning a real value from 0.0 through 1.0 to each parameter included in a plurality of parameters to generate a first design vector included in the first plurality of design vectors.

18. The one or more non-transitory computer readable media of any of clauses 11-17, wherein generating the first plurality of layout designs comprises partitioning the first layout design into a plurality of neighborhoods based on a first design vector included in the first plurality of design vectors; and determining a first position and a first orientation of a first icon representing a first flexible spatial element that is shared among the plurality of neighborhoods based on the first design vector.

19. The one or more non-transitory computer readable media of any of clauses 11-18, wherein generating the first plurality of layout designs further comprises distributing a plurality of icons representing a plurality of flexible spatial elements across the plurality of neighborhoods.

20. In some embodiments, a system comprises one or more memories storing instructions and one or more processors coupled to the one or more memories that, when executing the instructions, perform the steps of generating a first plurality of layout designs for a building based on a first plurality of design vectors and a baseline layout design; executing, multiple times, a stochastic multi-agent virus simulator on a first layout design included in the first plurality of layout designs and a first simulation configuration to generate a first plurality of simulation results; computing a first risk score associated with both the first layout design and a first virus based on the first plurality of simulation results; executing one or more evolutionary operations on the first plurality of design vectors based on the first risk score and at least one other risk score to generate a second plurality of design vectors; and generating a second plurality of layout designs for the building based on the second plurality of design vectors and the baseline layout design, wherein at least a second layout design included in the second plurality of layout designs reduces a transmission of the first virus relative to the first plurality of layout designs.

Any and all combinations of any of the claim elements recited in any of the claims and/or any elements described in this application, in any fashion, fall within the contemplated scope of the embodiments and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method, or computer program product. Accordingly, aspects of the present disclosure may take the form of an entirely hardware embodiment, an entirely software embodiment (including firmware, resident software, micro-code, etc.), or an embodiment combining software and hardware aspects that may all generally be referred to herein as a “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory, Flash memory, an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general-purpose processors, special-purpose processors, application-specific processors, or field-programmable gate arrays.

The flowchart and block diagrams in the figures illustrate the architecture, functionality, and operation of possible implementations of systems, methods, and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating building designs that reduce virus transmissions, the method comprising:
generating a first plurality of layout designs for a building based on a first plurality of design vectors and a baseline layout design;
executing, multiple times, a stochastic multi-agent virus simulator on a first layout design included in the first plurality of layout designs and a first simulation configuration to generate a first plurality of simulation results;
computing a first risk score associated with both the first layout design and a first virus based on the first plurality of simulation results;
executing one or more evolutionary operations on the first plurality of design vectors based on the first risk score and at least one other risk score to generate a second plurality of design vectors; and
generating a second plurality of layout designs for the building based on the second plurality of design vectors and the baseline layout design, wherein at least a second layout design included in the second plurality of layout designs reduces a transmission of the first virus relative to the first plurality of layout designs.

2. The computer-implemented method of claim 1, wherein the at least one other risk score includes a second risk score associated with both a second layout design included in the first plurality of layout designs and the first virus.

3. The computer-implemented method of claim 1, wherein the first simulation configuration includes at least one of a simulation duration, a time step, a grid spacing, a plurality of initial health statuses, a plurality of mask-wearing statuses, one or more half-life values, or a diffusion coefficient.

4. The computer-implemented method of claim 1, wherein computing the first risk score comprises dividing a sum of a subset of air-based contamination values included in the first plurality of simulation results by a total number of virtual occupants having an initial health status of susceptible.

5. The computer-implemented method of claim 1, wherein executing, multiple times, the stochastic multi-agent virus simulator on the first layout design and the first simulation configuration causes the stochastic multi-agent virus simulator to simulate, multiple times, a spread of the first virus between multiple occupants in accordance with the first layout design.

6. The computer-implemented method of claim 1, wherein the one or more evolutionary operations include at least one of a parent selection operation, an elitist selection operation, a crossover operation, or a mutation operation.

7. The computer-implemented method of claim 1, further comprising randomly assigning a real value from 0.0 through 1.0 to each parameter included in a plurality of parameters to generate a first design vector included in the first plurality of design vectors.

8. The computer-implemented method of claim 1, wherein generating the first plurality of layout designs comprises:
partitioning the first layout design into a plurality of neighborhoods based on a first design vector included in the first plurality of design vectors; and
determining a first position and a first orientation of a first icon representing a first flexible spatial element that is shared among the plurality of neighborhoods based on the first design vector.

9. The computer-implemented method of claim 8, wherein generating the first plurality of layout designs further comprises distributing a plurality of icons representing a plurality of flexible spatial elements across the plurality of neighborhoods.

10. The computer-implemented method of claim 1, further comprising:
performing at least one ranking operation on at least the second plurality of layout designs based on a second plurality of risk scores associated with both the second plurality of layout designs and the first virus to generate a ranked layout design list; and
displaying at least a portion of the ranked layout design list within a graphical user interface.

11. One or more non-transitory computer readable media including instructions that, when executed by one or more processors, cause the one or more processors to generate building designs that reduce virus transmissions by performing the steps of:
generating a first plurality of layout designs for a building based on a first plurality of design vectors and a baseline layout design;
executing, multiple times, a stochastic multi-agent virus simulator on a first layout design included in the first plurality of layout designs and a first simulation configuration to generate a first plurality of simulation results;
computing a first risk score associated with both the first layout design and a first virus based on the first plurality of simulation results;
executing one or more evolutionary operations on the first plurality of design vectors based on the first risk score and at least one other risk score to generate a second plurality of design vectors; and
generating a second plurality of layout designs for the building based on the second plurality of design vectors and the baseline layout design, wherein at least a second layout design included in the second plurality of layout designs reduces a transmission of the first virus relative to the first plurality of layout designs.

12. The one or more non-transitory computer readable media of claim 11, wherein the at least one other risk score includes a second risk score associated with both the first layout design and a second virus.

13. The one or more non-transitory computer readable media of claim 11, wherein the first simulation configuration includes at least one of a simulation duration, a time step, a grid spacing, a plurality of initial health statuses, a plurality of mask-wearing statuses, one or more half-life values, or a diffusion coefficient.

14. The one or more non-transitory computer readable media of claim 11, wherein computing the first risk score comprises dividing a sum of a subset of surface-based contamination values included in the first plurality of simulation results by a total number of virtual occupants having an initial health status of susceptible.

15. The one or more non-transitory computer readable media of claim 11, wherein the baseline layout design includes a building outline, one or more floor outlines, a plurality of positions associated with a plurality of fixed spatial elements, and a plurality of orientations associated with the plurality of fixed spatial elements.

16. The one or more non-transitory computer readable media of claim 11, wherein the one or more evolutionary operations include at least one of a parent selection operation, an elitist selection operation, a crossover operation, or a mutation operation.

17. The one or more non-transitory computer readable media of claim 11, further comprising randomly assigning a real value from 0.0 through 1.0 to each parameter included in a plurality of parameters to generate a first design vector included in the first plurality of design vectors.

18. The one or more non-transitory computer readable media of claim 11, wherein generating the first plurality of layout designs comprises:
partitioning the first layout design into a plurality of neighborhoods based on a first design vector included in the first plurality of design vectors; and
determining a first position and a first orientation of a first icon representing a first flexible spatial element that is shared among the plurality of neighborhoods based on the first design vector.

19. The one or more non-transitory computer readable media of claim 18, wherein generating the first plurality of layout designs further comprises distributing a plurality of icons representing a plurality of flexible spatial elements across the plurality of neighborhoods.

20. A system comprising:
one or more memories storing instructions; and
one or more processors coupled to the one or more memories that, when executing the instructions, perform the steps of:
generating a first plurality of layout designs for a building based on a first plurality of design vectors and a baseline layout design;
executing, multiple times, a stochastic multi-agent virus simulator on a first layout design included in the first plurality of layout designs and a first simulation configuration to generate a first plurality of simulation results;
computing a first risk score associated with both the first layout design and a first virus based on the first plurality of simulation results;
executing one or more evolutionary operations on the first plurality of design vectors based on the first risk score and at least one other risk score to generate a second plurality of design vectors; and
generating a second plurality of layout designs for the building based on the second plurality of design vectors and the baseline layout design, wherein at least a second layout design included in the second plurality of layout designs reduces a transmission of the first virus relative to the first plurality of layout designs.
